(19) United States
(12) Patent Application Publication
(10) Pub. No.: US 2014/0294583 A1
(43) Pub. Date: Oct. 2, 2014

(54) CONTROL SYSTEM AND METHOD FOR FANS

(71) Applicant: HON HAI PRECISION INDUSTRY CO., LTD., New Taipei (TW)

(72) Inventor: MENG-CHE YU, New Taipei (TW)

(73) Assignee: HON HAI PRECISION INDUSTRY CO., LTD., New Taipei (TW)

(21) Appl. No.: 14/224,222

(22) Filed: Mar. 25, 2014

(30) Foreign Application Priority Data
Mar. 27, 2013 (TW) 102111020

(51) Int. Cl. H05K 7/20; F04D 27/00

(52) U.S. Cl. CPC H05K 7/20136; F04D 27/004
USPC 416/1; 361/695

(57) ABSTRACT

A control system and method for controlling the speeds of heat-dissipating fans is applied to a plurality of voltage regulator downs (VRD), a plurality of chip devices, and a detecting chip. The VRD provides voltages for a plurality of chip devices, and outputs information as to electrical consumption of the corresponding chip device. The detecting chip controls rotation speed of the corresponding fan and of fans adjacent to that according to the consumption information.

### FIELD

The present disclosure relates to a control system and method for fans.

### BACKGROUND

As the performance of electronic chips improves, more and more heat is generated by the electronic chip during operation. Hence, a plurality of fans is adapted to dissipate heat generated by the electronic chip, according to the temperature of the electronic chip. However, the heat being generated and the temperature reflected are not synchronized, causing the necessary change in the rotation speed of the fans to be delayed. The electronic chip can malfunction when operating at an unsuitable temperature.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a block diagram of an example embodiment of a control system for fans of the present disclosure.

FIG. 2 is a flow chart of an example embodiment of a control method for fans of the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

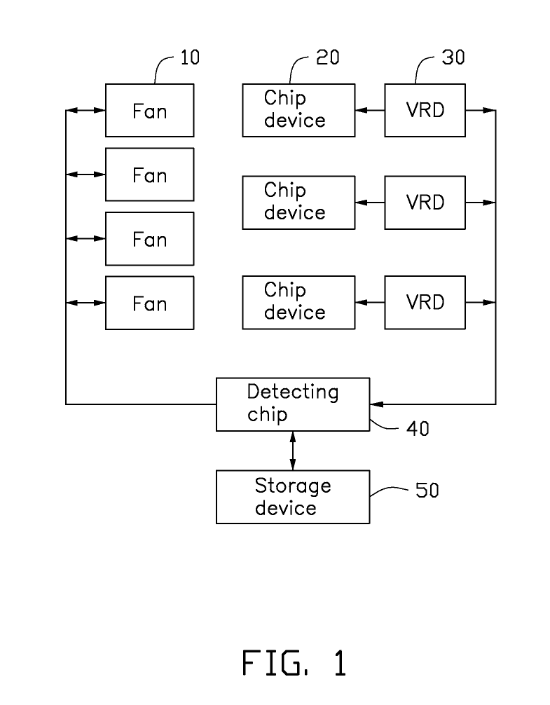

FIG. 1 shows a control system of the present disclosure. The control system comprises a plurality of fans 10, a plurality of voltage regulator downs (VRDs) 30 providing voltage for a plurality of chip devices 20, a detecting chip 40 coupled with the VRDs 30, and a storage device 50. In an embodiment, each VRD 30 provides voltage for a corresponding chip device 20. In other embodiments, each VRD 30 can provide voltages for two or more chip devices 20. Each VRD 30 can communicate with the detecting chip 40 through a power management bus (PMBus) or an inter-integrated circuit (I2C) bus.

The detecting chip 40 can obtain electrical consumption information about the plurality of chip devices 20 through corresponding VRDs 30. In an embodiment, the VRDs 30 outputs current and/or power of the corresponding chip device 20 to the detecting chip 40.

In an embodiment, the plurality of fans 10 is adapted to dissipate heat generated by the chip devices 20. The heat from each chip device 20 can be dissipated through one or more fans 10. For example, a first chip device dissipates heat through a first fan; and a second chip device dissipates heat through a second fan and a third fan.

The storage device 50 can store the maximum rotation speed of each fan 10.

The detecting chip 40 can further control rotation speed of the fans according to the consumption information, to dissipate heat more efficiently other than being based only on actual temperature. For example, when a VRD 30 outputs first consumption information about the first chip device, the detecting chip 40 controls the first fan to operate with 0.6 times of the maximum rotation speed of the first fan. In another embodiment, when a VRD 30 outputs second consumption information about the second chip device, where the information as to consumption shows greater than the first consumption, the detecting chip 40 controls the second and third fans to operate with 0.8 times of the maximum rotation speeds of the second and third fans respectively.

In another embodiment, the detecting chip further determines whether an operation time of the fan 10 with a rotation speed being greater than a predetermined speed exceeds a predetermined time. If the fan 10 with the rotation speed greater than the predetermined speed exceeds the predetermined time, this indicates that the heat generated by the corresponding chip device 20 needs external rotation speed of the fan 10 to satisfy the requirement. The detecting chip 40 speeds up the rotation speed of the adjacent fan. In an embodiment, the predetermined speed can be set as the maximum speed of the fan. In another embodiment, the predetermined speed can be also set as 0.8 times of the maximum speed of the fan. For example, when the operation time of the first fan with the rotation speed being greater than the predetermined speed exceeds the predetermine time, the detecting chip 40 then can speed up the rotation speed of the second fan which is adjacent to the first fan.

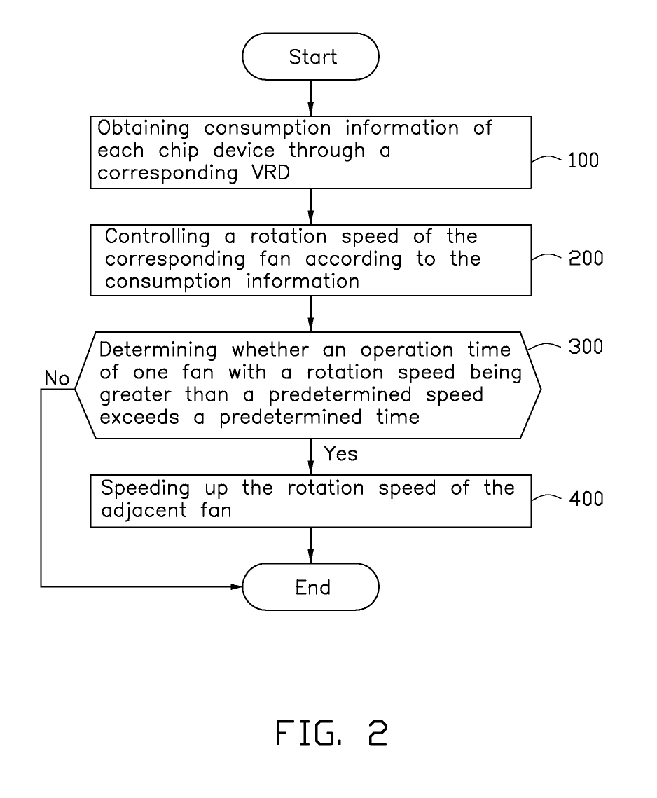

FIG. 2 shows an example embodiment of a control method of the present disclosure.

In 100, the detecting chip can obtain information as to electrical consumption of each chip device through the corresponding VRD.

In 200, the detecting chip can control the rotation speed of the corresponding fan 10 according to the consumption information.

In 300, the detecting chip 40 can determine whether the operation time of one fan with the rotation speed greater than the predetermined speed exceeds the predetermined time. If the operation time of the fan with rotation speed greater than the predetermined speed exceeds the predetermined time, 400 can be implemented. Otherwise, the process ends.

In 400, the detecting chip can speed up the rotation speed of an adjacent fan.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A control system, comprising:
a plurality of voltage regulator down (VRD) providing voltage for a plurality of chip devices, and outputting consumption information of the corresponding chip device;
a plurality of fans dissipating heat generated by the plurality of chip devices; and
a detecting chip controlling rotation speed of the corresponding fan according to the consumption information.

2. The control system of claim 1, wherein the consumption information comprises current outputted to the corresponding chip device by the VRD.

3. The control system of claim 1, wherein the consumption information comprises power outputted to the corresponding chip device by the VRD.

4. The control system of claim 1, wherein the detecting chip further determines whether an operation time of one fan with rotation speed being greater than a predetermined speed exceeds a predetermined time, the detecting chip further speeds up the rotation speed of one or more adjacent fans in response to the operation time of the fan with rotation speed being greater than a predetermined speed exceeding the predetermined time.

5. The control system of claim 4, wherein the consumption information comprises current outputted to the corresponding chip device by the VRD.

6. The control system of claim 4, wherein the consumption information comprises power outputted to the corresponding chip device by the VRD.

7. The control system of claim 4, further comprising:
a storage device storing maximum rotation speed of each fan;
wherein the detecting chip defines the maximum rotation speed of each fan as the predetermined speed.

8. The control system of claim 4, further comprising:
a storage device storing maximum rotation speed of each fan;
wherein the detecting chip defines 0.8 times of the maximum rotation speed of each fan as the predetermined speed.

9. A control method, comprising:
providing voltage for a plurality of chip devices by a plurality of voltage regulator downs (VRD);
obtaining consumption information of each chip device through a corresponding VRD; and
controlling a rotation speed of a corresponding fan according to the consumption information.

10. The control method of claim 9, wherein the consumption information comprises current outputted to the corresponding chip device by the VRD.

11. The control method of claim 9, wherein the consumption information comprises power outputted to the corresponding chip device by the VRD.

12. The control method of claim 9, further comprising:
determining whether an operation time of one fan with a rotation speed being greater than a predetermined speed exceeds a predetermined time; and
speeding up the rotation speed of an adjacent fan.

13. The control method of claim 12, wherein the consumption information comprises current outputted to the corresponding chip device by the VRD.

14. The control method of claim 12, wherein the consumption information comprises power outputted to the corresponding chip device by the VRD.

15. The control method of claim 12, further comprising:
a storage device storing maximum rotation speed of each fan;
wherein the detecting chip defines the maximum rotation speed of each fan as the predetermined speed.

16. The control method of claim 12, further comprising:
a storage device storing maximum rotation speed of each fan;
wherein the predetermined speed is defined with 0.8 times of the maximum rotation speed of each fan.
